(19) United States
(12) Patent Application Publication
(10) Pub. No.: US 2013/0083471 A1
(43) Pub. Date: Apr. 4, 2013

(54) MOUNTING APPARATUS FOR DATA STORAGE DEVICE

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/283,621

(22) Filed: Oct. 28, 2011

(30) Foreign Application Priority Data
Sep. 30, 2011 (CN) 201110297078.0

(51) Int. Cl. G06F 1/16; H05K 7/00

(52) U.S. Cl. 361/679.31; 248/274.1

(57) ABSTRACT

A mounting apparatus for mounting a data storage device includes a mounting plate, first and second mounting members, and a connecting member movably connected between the first and second mounting members. The first mounting member is fixed to a side of the data storage device. The connecting member is adjustable to move the second mounting member toward or away from the first mounting member, thereby sandwiching or releasing the data storage device. The mounting members are fixable to the mounting plate.

### BACKGROUND

1. Technical Field

The present disclosure relates to a mounting apparatus for a data storage device.

2. Description of Related Art

An electronic device, such as a computer, is generally equipped with a data storage device, such as a hard disk drive. Mounting the storage device to the electronic device by traditional screw type fasteners is inefficient and always requires tools, such as a screwdriver.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a mounting apparatus and a data storage device.

FIG. 2 is an exploded, isometric view of FIG. 1.

FIG. 3 is an inverted view of FIG. 2.

FIG. 4 is a partially assembled view of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

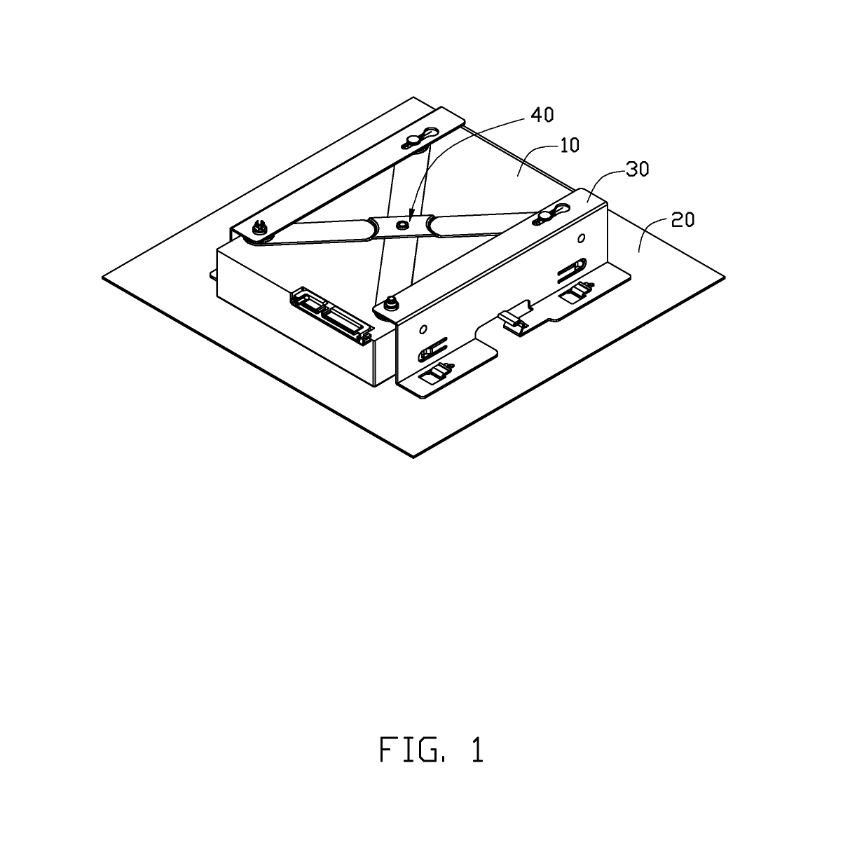

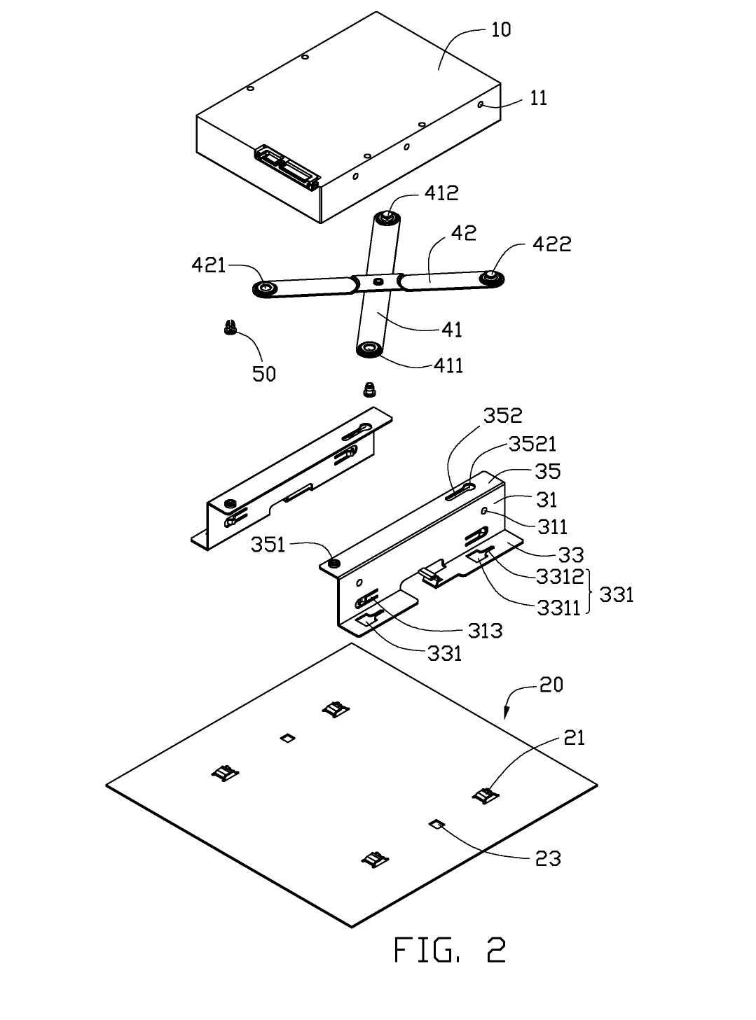

Referring to FIG. 1, an exemplary embodiment of a mounting apparatus is provided for mounting a data storage device 10, such as a hard disk drive. The mounting apparatus includes a mounting plate 20, two mounting members 30, a connecting member 40, and two fasteners 50 (labeled in FIG. 2).

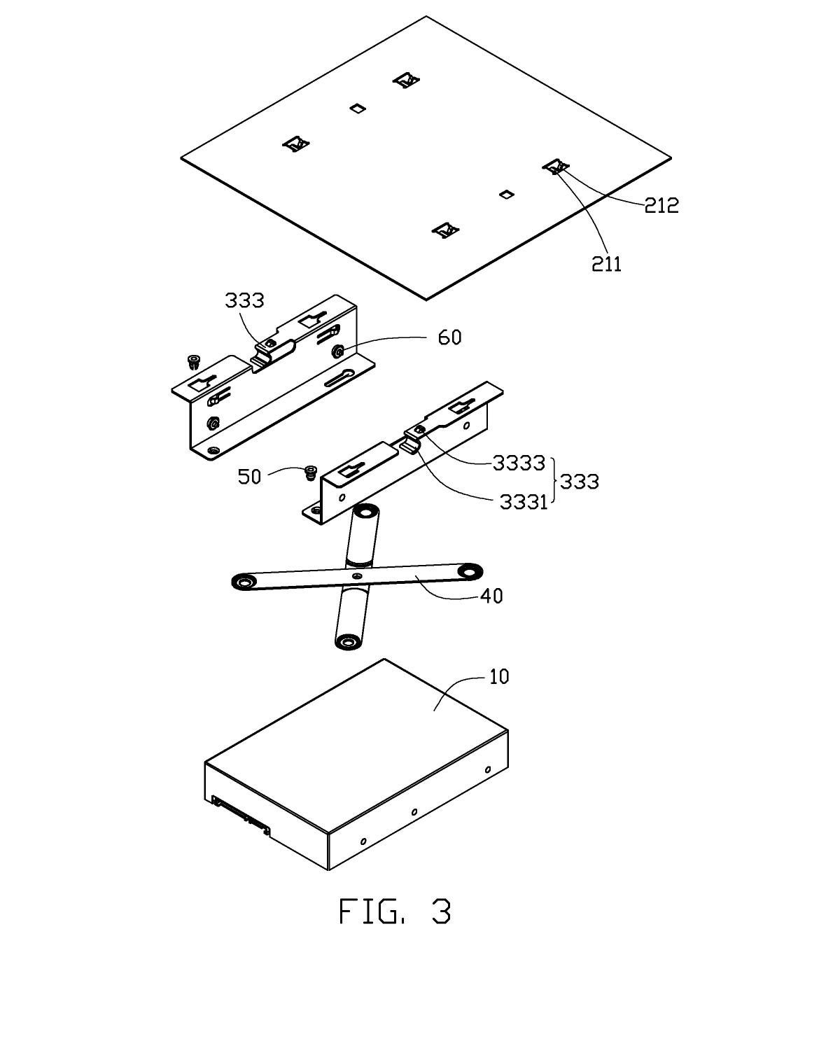

Referring to FIG. 2 and FIG. 3, the data storage device 10 defines a plurality of mounting holes 11 in opposite sides.

Two locking portions 21 protrude from each side of the mounting plate 20. Each locking portion 21 includes a wide blocking piece 211 at a first end of the locking portion 21, and a narrow connecting piece 212 at a second end of the locking portion 21. A positioning hole 23 is defined in the mounting plate 20 between the locking portions 21 of each side of the mounting plate 20.

Each mounting member 30 is substantially Z-shaped in cross-section and includes a fixing plate 31, a locking plate 33 perpendicularly extending out from a first side of the fixing plate 31, and a connecting plate 35 perpendicularly extending in from a second side of the fixing plate 31 away from the locking plate 33. The fixing plate 31 defines two through holes 311 corresponding to the mounting holes 11. A resilient piece 313 is formed in the fixing plate 31 adjacent to and below each through hole 311. The locking plate 33 defines two locking slots 331 corresponding to the locking portions 21 of one side of the mounting plate 20. Each locking slot 331 includes a large inlet 3311 and a small latching hole 3312 communicating with the inlet 3311. A resilient latch 333 is formed on the locking plate 33, between the locking slots 331. The latch 333 includes a handle 3331 extending up from a distal end of the latch portion 333, and a raised protrusion 3333 formed on the bottom of the latch 333 and adjacent to the handle 3331. A pivot hole 351 and an elongated slide slot 352 are respectively defined in opposite ends of the connecting plate 35. The slide slot 352 includes a large access 3521 away from the pivot hole 351.

The connecting member 40 includes a first pole 41 and a second pole 42 pivotably connected to the first pole 41 in the middles of the first pole 41 and the second pole 42. Therefore, the first pole 41 is angled from the second pole 42. A first through hole 411 is defined in a first end of the first pole 41. A second through hole 421 is defined in a first end of the second pole 42. A first post 412 extends up from a second end of the first pole 41 opposite to the first through hole 411. A second post 422 extends up from a second end of the second pole 42 opposite to the second through hole 421. The first and second posts 412 and 422 are both mushroom shaped.

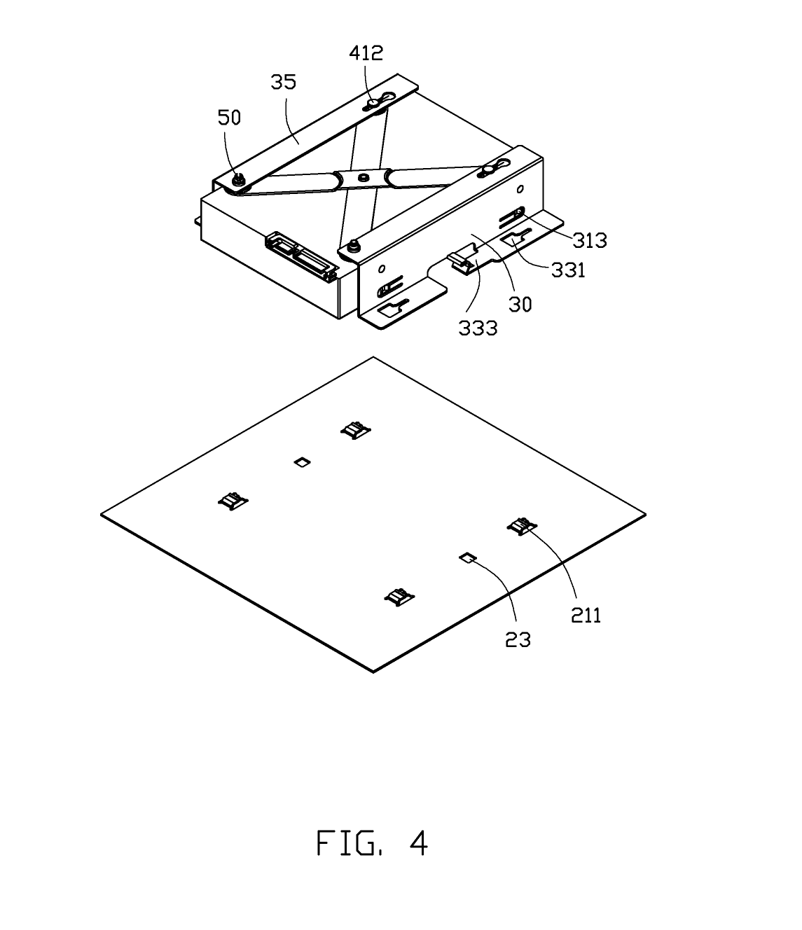

Referring to FIG. 1 and FIG. 4, in assembly, the first and second posts 412 and 422 are slidably inserted into the slide slots 352 of the corresponding mounting members 30 through the access 3521, respectively. One fastener 50 extends through the pivot hole 351 of one connecting plate 35 and the first through hole 411 to pivotably attach the first pole 41 to the connecting plate 35. The other fastener 50 extends through the pivot hole 351 of the other connecting plate 35 and the second through hole 421 to pivotably attach the second pole 42 to the other connecting plate 35. The data storage device 10 is arranged between the mounting members 30. The connecting member 40 is adjusted to slide the first and second posts 412 and 422 in the slide slots 352 until the data storage device 10 is sandwiched between the mounting members 30. Two screws 60 (shown in FIG. 3) extend through the through holes 311 of one mounting member 30 to screw into the mounting holes 11 of one corresponding side of the data storage device 10. The resilient pieces 313 abut against the data storage device 10.

The mounting members 30 together with the data storage device 10 are set on the mounting plate 20. The blocking pieces 211 are inserted into the corresponding locking slots 331 through the inlets 3311, respectively. The mounting members 30 are moved until the blocking pieces 211 are engaged in the latching holes 3312, and the protrusions 3333 are engaged in the positioning holes 23.

In disassembly, the handles 3331 are pulled to release the protrusions 3333 from the positioning holes 23. The mounting members 30 are moved to release the locking portions 21 from the corresponding locking slots 331. The mounting members 30 are then moved away from each other. The screws 60 are released to release the data storage device 10.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A mounting apparatus for mounting a data storage device, comprising:
a mounting plate;
first and second mounting members; and
a connecting member movably connected between the mounting members;
wherein the data storage device is to be fixed to the first mounting member, the connecting member is adjustable to move the second mounting member toward or away from the first mounting member, thereby sandwiching or releasing the data storage device together with the first mounting member, the first and second mounting members are fixable to the mounting plate.

2. The mounting apparatus of claim 1, wherein the mounting plate comprises two locking portions respectively corresponding to the first and second mounting members, and defines two positioning holes respectively corresponding to the first and second mounting members, each of the first and second mounting members forms a raised protrusion engagable in the corresponding positioning hole and defines a locking slot, the corresponding locking portion is locked to the locking slot.

3. The mounting apparatus of claim 2, wherein each locking portion comprises a blocking piece, each locking slot comprises a great inlet and a small latching hole communicating with the inlet, the blocking piece is insertable into the latching hole through the inlet.

4. The mounting apparatus of claim 1, wherein each of the first and second mounting members comprises a fixing plate attached to a corresponding side of the data storage device, a locking plate extending out from a bottom side of the fixing plate, and a connecting plate extending in from a top side of the fixing plate, the locking plate is fixed to the mounting plate, the connecting member connects to the connecting plate.

5. The mounting apparatus of claim 4, wherein the fixing plate forms a resilient piece abutting against the side of the data storage device.

6. The mounting apparatus of claim 4, wherein a resilient latch is formed from a middle of the locking plate, the latch comprises a handle formed up from a distal end of the latch and a protrusion formed on a bottom of the latch adjacent to the handle, the mounting plate defines two positioning holes respectively corresponding to the first and second mounting members, the protrusion is engagable in the corresponding positioning hole, the handle is operable to be pulled to release the protrusion from the corresponding positioning hole.

7. The mounting apparatus of claim 1, wherein the connecting member comprises a first pole and a second pole pivotably connected to the first pole in middles of the first pole and the second pole, therefore, the first pole is angled from the second pole.

8. The mounting apparatus of claim 7, wherein each of the first and second mounting members comprises a connecting plate, a first end of the first pole and a first end of the second pole are pivotably attached to the connecting plates respectively.

9. The mounting apparatus of claim 8, wherein a first post extends on a second end of the first pole, a second post extends on a second end of the second pole, each of the connecting plates defines a slide slot, the first post and the second post are slidably engaged in the corresponding slide slots.

10. The mounting apparatus of claim 9, wherein the first and second posts are both mushroom shaped.

11. An assembly, comprising:
a data storage device;
a mounting plate;
first and second mounting members; and
a connecting member movably connected between the mounting members;
wherein the data storage device is fixed to the first mounting member, the connecting member is adjustable to move the second mounting member toward or away from the first mounting member, to sandwich or release the data storage device together with the first mounting member, the first and second mounting members are fixable to the mounting plate.

12. The assembly of claim 11, wherein the mounting plate comprises two locking portions respectively corresponding to the first and second mounting members, and defines two positioning holes respectively corresponding to the first and second mounting members, each of the first and second mounting members forms a raised protrusion engagable in the corresponding positioning hole and defines a locking slot, the corresponding locking portion is locked to the locking slot.

13. The assembly of claim 12, wherein each locking portion comprises a blocking piece, each locking slot comprises a great inlet and a small latching hole communicating with the inlet, the blocking piece is insertable into the latching hole through the inlet.

14. The assembly of claim 11, wherein each of the first and second mounting members comprises a fixing plate attached to a corresponding side of the data storage device, a locking plate extending out from a bottom side of the fixing plate, and a connecting plate extending in from a top side of the fixing plate, the locking plate is fixed to the mounting plate, the connecting member connects to the connecting plate.

15. The assembly of claim 14, wherein the fixing plate forms a resilient piece abutting against the corresponding side of the data storage device.

16. The assembly of claim 14, wherein a resilient latch is formed from a middle of the locking plate, the latch comprises a handle formed up from a distal end of the latch and a protrusion formed on a bottom of the latch adjacent to the handle, the mounting plate defines two positioning holes respectively corresponding to the first and second mounting members, the protrusion is engagable in the corresponding positioning hole, the handle is operable to be pulled to release the protrusion from the corresponding positioning hole.

17. The assembly of claim 11, wherein the connecting member comprises a first pole and a second pole pivotably connected to the first pole in middles of the first pole and the second pole.

18. The assembly of claim 17, wherein each of the first and second mounting member comprises a connecting plate, a first end of the first pole and a first end of the second pole are pivotably attached to the connecting plates respectively.

19. The assembly of claim 18, wherein a first post extends on a second end of the first pole, a second post extends on a second end of the second pole, each of the connecting plates defines a slide slot, the first post and the second post are slidably engaged in the slide slots.

20. The assembly of claim 19, wherein the first and second posts are both mushroom shaped.
